(19) United States
(12) Patent Application Publication
(10) Pub. No.: US 2009/0277676 A1
(43) Pub. Date: Nov. 12, 2009

(54) IN-MOLD DECORATION DEVICE AND MANUFACTURING METHOD THEREOF

(75) Inventors: Mu-Tsai Chang, Taipei (TW); Fu-Ming Chen, Taipei (TW); Sei-Wo Tseng, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipei (TW)

(21) Appl. No.: 12/429,188

(22) Filed: Apr. 24, 2009

(30) Foreign Application Priority Data
May 12, 2008 (TW) 97117453

(51) Int. Cl. H05K 1/16; H05K 3/00

(52) U.S. Cl. 174/260; 427/97.3

(57) ABSTRACT

An in-mold decoration (IMD) device and a manufacturing method thereof are provided. The manufacturing method of the IMD device includes following steps. First, a patterned film is formed. The patterned film includes a pattern layer and a film layer located below the pattern layer. A conductive layer is then formed on the film layer. Next, the conductive layer is connected to an electrical connection element. Thereafter, a resin layer is formed on the conductive layer.

### CROSS-REFERENCE TO RELATED APPLICATION

This application claims the priority benefit of Taiwan application serial no. 97117453, filed May 12, 2008. The entirety of the above-mentioned patent application is hereby incorporated by reference herein and made a part of specification.

### BACKGROUND OF THE INVENTION

1. Field of the Invention

The present invention relates to an in-mold decoration (IMD) device and a manufacturing method thereof More particularly, the present invention relates to an IMD device capable of preventing electrostatic discharge (ESD) and a manufacturing method of said IMD device.

2. Description of Related Art

An IMD device is manufactured by performing an ink printing process, a forming process, a trimming process, a resin injection process, and so on, whereby components suitable for being used in information home appliances, in automobiles for interior decoration, and in consumer electronic products including computers and communication products are fabricated. Note that a conductive layer is formed on a resin layer after the resin injection process is implemented according to the pertinent art. In addition, when the components are integrated into an electronic device, e.g., a circuit board, the conductive layer is electrically connected to a ground circuit within the electronic device. Hence, when the consumer electronic products including the computers and the communication products are used by a user, electrostatic charges carried by the user are transmitted from fingers of the user to the electronic products, and an electrostatic current caused by ESD can be directed out because of the electrical connection between the conductive layer and the ground circuit. The electronic products can be prevented from being damaged by ESD accordingly.

Nonetheless, when the component is integrated into an electronic device, e.g. a circuit board, the conductive layer is apt to be improperly worn because the conductive layer is formed on an outer surface of the component. As such, it is rather difficult for the electrostatic current generated by ESD to be conducted to the ground circuit through the conductive layer. In other words, the electrostatic current is likely to be conducted to electrical elements on the circuit board, thus resulting in damages to the electrical elements and abnormal operation of the entire electronic product.

### SUMMARY OF THE INVENTION

The present invention provides a manufacturing method of an IMD device. The manufacturing method of the IMD device includes following steps. First, a patterned film is formed. The patterned film includes a pattern layer and a film layer located below the pattern layer. A conductive layer is then formed on the film layer. Next, the conductive layer is connected to an electrical connection element. Thereafter, a resin layer is formed on the conductive layer.

The present invention further provides an IMD device suitable for being electrically connected to a ground circuit of an electronic device. The IMD device includes a patterned film, a conductive layer, and a resin layer. The conductive layer is disposed on the patterned film and is suitable for being electrically connected to a ground circuit. The resin layer is disposed on the conductive layer.

In the present invention, the conductive layer is first formed on the patterned film, and the resin layer is then formed on the conductive layer. As such, the conductive layer can be prevented from being improperly worn in subsequent manufacturing processes and can still be equipped with a function of ESE protection.

In order to make the aforementioned and other features and advantages of the present invention more comprehensible, an embodiment accompanied with figures is described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a flowchart showing a manufacturing method of an IMD device according to an embodiment of the present invention.

FIGS. 2A through 2F are cross-sectional flowcharts showing steps of manufacturing the IMD device according to an embodiment of the present invention.

FIG. 3 is a schematic view showing the IMD device of FIG. 2F is assembled to an electronic device.

### DESCRIPTION OF EMBODIMENTS

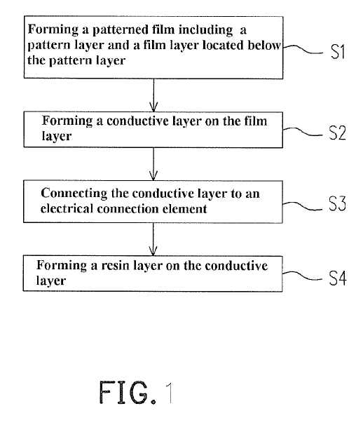

FIG. 1 is a flowchart showing a manufacturing method of an IMD device according to an embodiment of the present invention. In the present embodiment, a manufacturing method of an IMD device is provided. Referring to FIG. 1, the manufacturing method of the IMD device in the present embodiment includes following steps. First, in step S1, a patterned film is formed. The patterned film includes a pattern layer and a film layer located below the pattern layer. Next, in step S2, a conductive layer is formed on the film layer. After that, in step S3, the conductive layer is connected to an electrical connection element. Thereafter, in step S4, a resin layer is formed on the conductive layer. With a view to better understanding said manufacturing method of the IMD device, cross-sectional flowcharts are provided below to elaborate the manufacturing method of the IMD device according to the present embodiment.

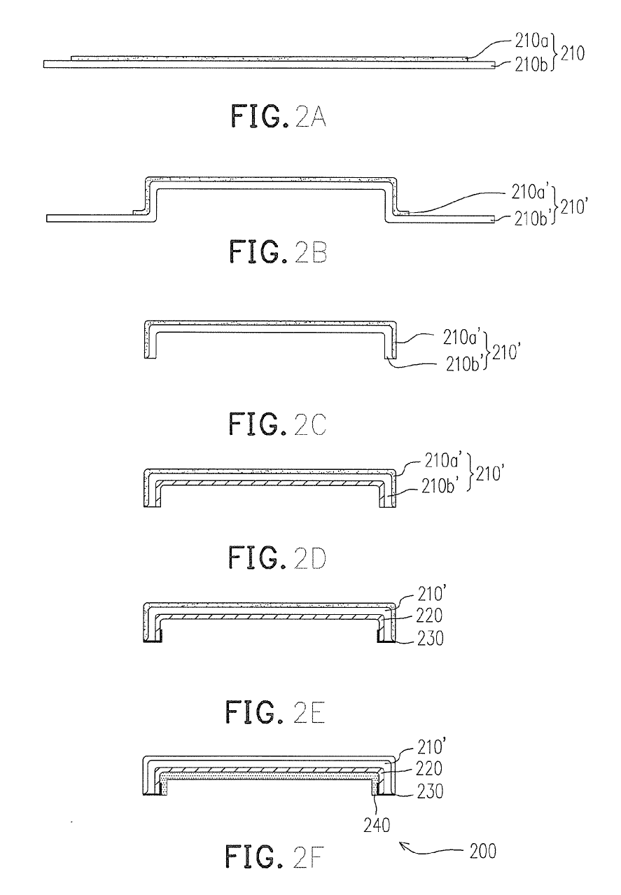

FIGS. 2A through 2F are cross-sectional flowcharts showing steps of manufacturing the IMD device according to an embodiment of the present invention. In the manufacturing method of the IMD device of the present embodiment, a patterned film 210 is first formed as shown in FIG. 2A. The patterned film 210 includes a pattern layer 210a and a film layer 210b located below the pattern layer 210a. According to the present embodiment, the pattern layer 210a is, for example, an ink layer, and the film layer 210b can be an in-mold printing film.

Next, as indicated in FIG. 2B, the patterned film 210 is thermal-compressed to form a molded patterned film 210′. In the present embodiment, the pattern layer 210a and the film layer 210b are, for example, respectively thermal-compressed to form a molded pattern layer 210a′ and a molded film layer 210b′.

After that, as shown in FIGS. 2C and 2D, a conductive layer 220 is formed on the molded film layer 210b′. In the present embodiment, the molded patterned film 210′ can be first trimmed (as shown in FIG. 2C), so as to allow the molded patterned film 210′ to have a proper dimension. Thereafter, a sputtering process can be performed to form the conductive layer 220 on the molded film layer 210b′ (as shown in FIG. 2D).

After the formation of the conductive layer 220, a resin layer 240 is formed as shown in FIGS. 2E and 2F. In the present embodiment, the conductive layer 220 is connected to an electrical connection element 230 (as shown in FIG. 2E), and the resin layer 240 is then formed on the conductive layer 220 and a portion of the electrical connection element 230 (as shown in FIG. 2F). The resin layer 240 covers the conductive layer 220 and the portion of the electrical connection element 230. Thereby, the fabrication of the IMD device 200 in the present embodiment is completed. Here, the IMD device 200 is, for example, a component suitable for being used in information home appliances, in automobiles for interior decoration, and in consumer electronic products including computers and communication products.

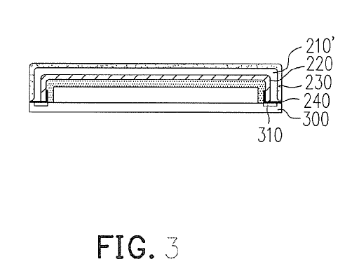

FIG. 3 is a schematic view showing the IMD device of FIG. 2F is assembled to an electronic device. Referring to FIG. 3, as the IMD device 200 of FIG. 2F is assembled to an electronic device 300, e.g., a circuit board, the electrical connection element 230 in the IMD device 200 is suitable for being electrically connected to a ground circuit 310 of the circuit board. Thereby, when a user touches a component applied in information home appliances, in automobiles for interior decoration, and in consumer electronic products including computers and communication products, an electrostatic current carried by the user can be directed out on account of the electrical connection among the conductive layer 220, the electrical connection element 230, and the ground circuit 310, so as to prevent the electronic device 300 from being damaged by ESD.

In the present embodiment, the electrical connection element 230 which is electrically connected to the ground circuit 310 is additionally formed on the conductive layer 220. However, in another embodiment, the conductive layer 220 can also be electrically connected to the ground circuit 310 directly without being electrically connected to the electrical connection element 230.

In light of the foregoing, according to the present invention, the conductive layer is formed on the patterned film at first, and the resin layer is then formed on the conductive layer. By means of the resin layer, the conductive layer can be prevented from being improperly worn in subsequent manufacturing processes. Accordingly, in comparison with the conductive layer of the pertinent art, the conductive layer of the present invention is not prone to be improperly worn during the assembly of the IMD device to other components. Namely, after the assembly of the entire electronic product is completed, the conductive layer of the present invention can still conduct the electrostatic current generated by ESD to the ground circuit in an effective manner, so as to ensure that the electrostatic current is directed out and the electronic product can still be equipped with the function of ESD protection. As such, lifetime of the electronic product can be extended.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of an in-mold decoration device, comprising:
forming a patterned film, the patterned film comprising a pattern layer and a film layer located below the pattern layer;
forming a conductive layer on the film layer;
connecting the conductive layer to an electrical connection element; and
forming a resin layer on the conductive layer.

2. The manufacturing method of the in-mold decoration device as claimed in claim 1, further comprising thermal-compressing the patterned film to form a molded patterned film after the patterned film is formed.

3. The manufacturing method of the in-mold decoration device as claimed in claim 2, further comprising trimming the molded patterned film after the molded patterned film is thermal-compressed.

4. The manufacturing method of the in-mold decoration device as claimed in claim 1, wherein the conductive layer is formed by performing a sputtering process.

5. The manufacturing method of the in-mold decoration device as claimed in claim 1, wherein the pattern layer is an ink layer.

6. The manufacturing method of the in-mold decoration device as claimed in claim 1, wherein the film layer is an in-mold printing film.

7. The manufacturing method of the in-mold decoration device as claimed in claim 1, wherein the electrical connection element is a conductive cloth.

8. The manufacturing method of the in-mold decoration device as claimed in claim 1, wherein the electrical connection element is a metallic leaf spring.

9. An in-mold decoration device, suitable for being electrically connected to a ground circuit of an electronic device, the in-mold decoration device comprising:
a patterned film;
a conductive layer, disposed on the patterned film, wherein the conductive layer is suitable for being electrically connected to the ground circuit; and
a resin layer, disposed on the conductive layer.

10. The in-mold decoration device as claimed in claim 9, further comprising an electrical connection element, the conductive layer being electrically connected to the ground circuit through the electrical connection element.

11. The in-mold decoration device as claimed in claim 10, wherein the resin layer covers the conductive layer and a portion of the electrical connection element.

12. The in-mold decoration device as claimed in claim 10, wherein the electrical connection element is a conductive cloth.

13. The in-mold decoration device as claimed in claim 10, wherein the electrical connection element is a metallic leaf spring.
